(19) United States
(12) Patent Application Publication
(10) Pub. No.: US 2010/0018463 A1
(43) Pub. Date: Jan. 28, 2010

(54) Plural Gas Distribution System

(76) Inventors: Chen-Hua Yu, Hsin-Chu (TW); Chien Ling Hwang, Hsin-Chu (TW)

Correspondence Address: SLATER & MATSIL, L.L.P., 17950 PRESTON ROAD, SUITE 1000, DALLAS, TX, 75252, US

(21) Appl. No.: 12/179,231

(22) Filed: Jul. 24, 2008

(51) Int. Cl. C23C 16/54

(52) U.S. Cl. 118/715

(57) ABSTRACT

A plural gas distribution system is presented. The system includes a chamber and a showerhead. The chamber is configured to contain and to exhaust a plurality of gases. The showerhead includes at least one multi-channel gas delivery tube with at least two sub-tubes within the multi-channel gas delivery tube, wherein the at least two sub-tubes are configured to simultaneously expel gases unmixed into the chamber.

### TECHNICAL FIELD

The present invention relates generally to a gas distribution system and more particularly, to a gas distribution system configured to deliver separate gases simultaneously.

### BACKGROUND

Group III-V semiconductors are used to make devices such as microwave frequency integrated circuits such as infrared light-emitting diodes, laser diodes, and solar cells. Group III-V semiconductors, such as gallium arsenide (GaAs) are compounds of two elements, gallium, and arsenic.

In order to form Group III-V semiconductor layer in a semiconductor device, gases containing the Group III-V elements are released into a chamber containing a workpiece. Group III and V elements react with each other to produce a corresponding Group III-V semiconductor, which deposits on the workpiece. The method in which the source gases are delivered into the chamber is important to the uniformity, purity, and structure of the eventual Group III-V semiconductor device.

A prior art system of delivering gases to a chamber includes premixing the source gases. A disadvantage of premixing the elements and then delivering the premixed gas to the chamber include maintenance problems with the equipment since premixed gases may react within the delivery system and precipitate in the delivery system. Further, some gases may not be premixed do to volatility or other factors.

Another prior art system includes sequentially delivering the gases into the chamber. The gas delivery system supplies a first gas, and then the gas delivery system supplies the second gas. The workpiece may be rotated under the gas delivery system. This process may be repeated as necessary to achieve the film thickness desired. A major disadvantage to this prior art system is that the workpiece may develop uniformity issues. A sharp concentration change may be necessary in the disposed layers which may not be obtained by the gas switching method of the prior art.

Yet another prior art system includes delivering one gas into one portion of the chamber and delivering another gas in another portion of the chamber. The workpiece may be rotated under the gas delivery system. This prior art system, however, may create films with uniformity problems, and decreased yield.

Thus, there is a need for a new gas distribution system that overcomes the above described shortcomings in the prior art.

### SUMMARY OF THE INVENTION

These and other problems are generally solved or circumvented, and technical advantages are generally achieved by a gas distribution system configured to deliver separate gases simultaneously.

In accordance with an illustrative embodiment of the present invention, a plural gas distributing system is presented. The system includes a chamber and a showerhead. The chamber is configured to contain and to exhaust a plurality of gases. The showerhead comprises at least one multi-channel gas delivery tube with at least two sub-tubes within the multi-channel gas delivery tube, wherein the at least two sub-tubes are configured to simultaneously expel gases unmixed into the chamber.

Advantages of preferred embodiments of the present invention include providing an apparatus and a system for delivering unmixed gases into a chamber, thereby allowing a greater control of uniformity of the films formed therein.

The foregoing has outlined rather broadly the features and technical advantages of an illustrative embodiment in order that the detailed description of the invention that follows may be better understood. Additional features and advantages of an illustrative embodiment will be described hereinafter, which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the illustrative embodiments as set forth in the appended claims.

### BRIEF DESCRIPTION OF THE DRAWINGS

For a more complete understanding of the illustrative embodiments, and the advantages thereof, reference is now made to the following descriptions taken in conjunction with the accompanying drawings, in which:

FIG. 1 illustrates a plural gas system in accordance with an embodiment of the present invention;

FIGS. 2A and 2B illustrate embodiments of showerheads with two-channel gas delivery tubes;

FIGS. 3A and 3B illustrate embodiments of showerheads with four-channel gas delivery tubes and five-channel gas delivery tubes respectively;

FIG. 4 illustrates gas interconnections and inlets included in the showerhead;

FIG. 5 illustrates an embodiment of a plural gas distribution system including chamber baffles;

FIG. 6 illustrates an embodiment of a plural gas distribution system wherein the showerhead comprises one gas delivery tube and the chamber includes a baffle; and

FIGS. 7A and 7B illustrates and embodiment of a plural gas distribution system with a concentric circle showerhead and concentric circle baffles.

Corresponding numerals and symbols in the different figures generally refer to corresponding parts unless otherwise indicated. The figures are drawn to clearly illustrate the relevant aspects of the preferred embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that an illustrative embodiment provides many applicable inventive concepts that can be embodied in a wide variety of specific contexts. The specific embodiments discussed are merely illustrative of specific ways to make and use the invention, and do not limit the scope of the invention.

The present invention will be described with respect to illustrative embodiments in a specific context, namely metal organic chemical vapor deposition (MOCVD) system for growing epitaxial layers on a workpiece. Embodiments may also be applied, however, to other semiconductor processing equipment such as etchers, furnaces, plasma reactors, and the like that may benefit from a plural gas distribution system and/or apparatus.

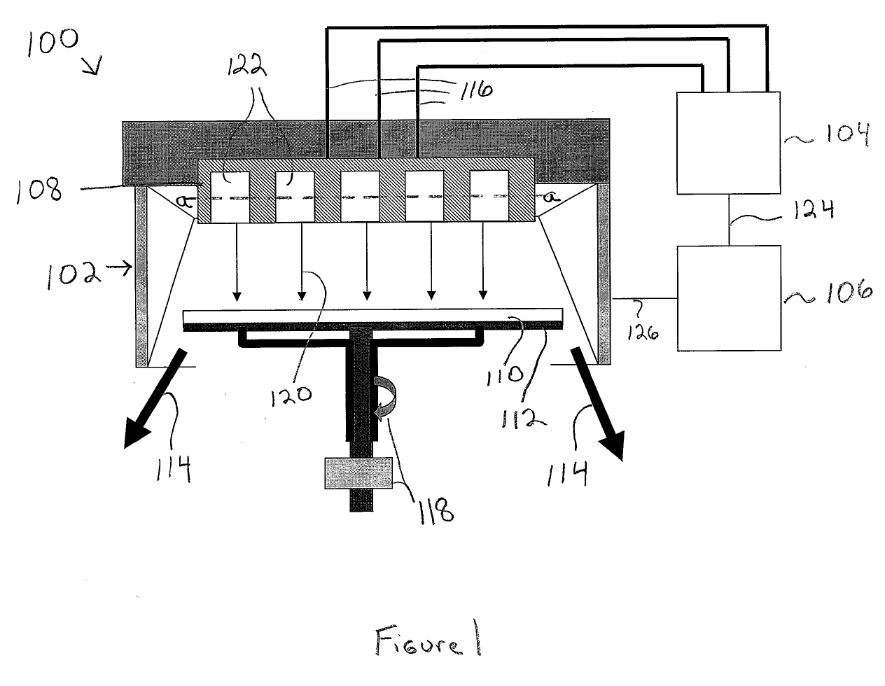

FIG. 1 illustrates a plural gas distribution system 100 in accordance with an embodiment of the present invention. Plural gas distribution system 100 comprises chamber 102, gas input area 104, and controller 106. Chamber 102 is capable of maintaining a vacuum, holding workpiece 110 on platen 112, and exhausting gases through exhaust ports 114. Further, showerhead 108 is disposed within chamber 102. Showerhead 108 is connected to gas input area 104, which feeds gas into showerhead 108. Showerhead 108 may receive multiple gases simultaneously from gas input area 104, through gas pipes 116. Showerhead 108 further comprises multi-channel gas delivery tubes 122. Mechanisms 118 may be in place to structurally support, heat, and rotate workpiece 110. In another embodiment, chamber 102 may be configured to hold multiple work pieces. A laminar flow is indicated by arrows 120. However, while FIG. 1 indicates laminar flow 120 of the gases to workpiece 110, the laminar flow may likely be disturbed by workpiece 110 rotation and other factors.

Gas input area 104 may be internal to plural gas distribution system 100, such as, for example, bottles of source gas, alternate gas sources, a valve system connected to an external gas distribution area, or the like. Alternately, gas input area 104 may be external to plural gas distribution system 100. In any case, multiple gases may be input simultaneously to showerhead 108, and through showerhead 108, gases may be simultaneously delivered to each multi-channel gas delivery tube 122 within chamber 102.

Controller 106 may be any appropriate microprocessor unit, including a computer internal or external to plural gas distribution system 100. Controller 106 may control the gas flow into showerhead 108 through connection 124. Further, controller 106 may control the temperature of workpiece 110, the rotation of workpiece 110, the vacuum and/or pumping of chamber 102, and the like, through connection 126.

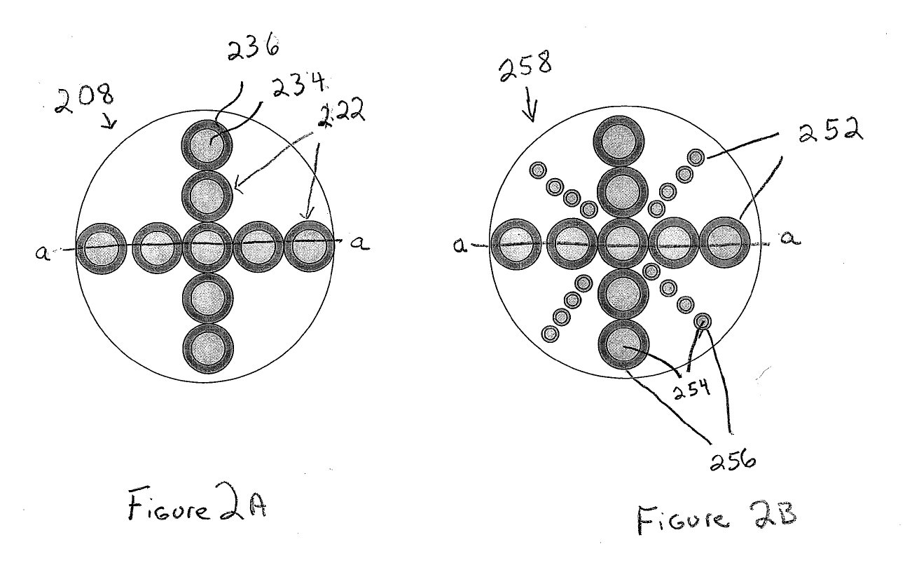

FIGS. 2A and 2B illustrate embodiments of showerhead 208 and 258 with multi-channel gas delivery tubes 122 that may be used as the showerhead 108 illustrated in FIG. 1. Turning first to FIG. 2A a view of an embodiment of showerhead 108 is shown along cross-section “a-a” of FIG. 1. Showerhead 208 is an embodiment of showerhead 108 and is shown from the perspective of workpiece 110 looking up at showerhead 108 and multi-channel gas delivery tubes 122 in FIG. 1A. In this embodiment, showerhead 208 comprises a cross pattern, for example, of two-channel gas delivery tubes 222. Showerhead 208 comprises nine two-channel gas delivery tubes 222, configured as an inner sub-tube 234 and an outer sub-tube 236.

Inner sub-tube 234 may have a first gas source fed in from a gas input area, such as gas input area 104 in FIG. 1 and may expel the first gas within the chamber (not shown). Further outer sub-tube 236 may have a second gas fed in from a gas input area and may expel the second gas into the chamber. Moreover, inner sub-tube 234 and outer sub-tube 236 expel first gas and second gas unmixed into the chamber, preferably such that the flow rates for inner sub-tube gases and outer sub-tube gases may be controlled independently. Preferably, the diameter of the outer sub-tube 256 is about one fifth of a workpiece diameter, and the diameter of the inner sub-tube 254 is about one tenth of a workpiece diameter.

The laminar flow produced by the first sub-tube and the second sub-tube may provide for a column of gas expelled from outer sub-tube 236 to encircle the column of gas expelled from inner sub-tube 234. The average diameter of outer sub-tube 236 may be between about one-tenth to about one-hundredth of a substrate diameter. The average diameter of inner sub-tube 234 may be between about one-tenth to about three-quarters of the diameter of the outer sub-tube 236.

In an alternate embodiment, a two-channel gas delivery tube may be comprised of two side-by-side channels, including a first sub-tube and a second sub-tube. The gases that flow in the first sub-tube and the gases that flow in the second sub-tube are independent of each other, and do not mix until expelled into the chamber. The gas flow rate may be controlled independently.

In a more specific example of an illustrative embodiment, a Group III/V film, such as GaAs may be produced by operation of showerhead 208. Gas delivery inner sub-tube 234 may have a Group III, such as gallium gas source fed in from a gas input area, such as gas input area 104 in FIG. 1 and may expel the Group III gas within the chamber (not shown). Further, outer sub-tube 236 may have a Group V gas, such as arsine, fed in from a gas input area and may expel Group V gas into the chamber. Moreover, inner sub-tube 234 and outer sub-tube 236 expel Group V gas and Group III gas unmixed into the chamber, providing for a uniform GaAs film. Those of ordinary skill in the art will appreciate that other Group V gases, for example phosphine and that Group III gas sources are trimethylgallium, and triethylgallium, for gallium, trimethylaluminum, and triethylaluminum for aluminum, and for an indium source trimethylindium, and the like may be used. Other gases and gas types may be used in other illustrated embodiments of the present invention, in either semiconductor process equipment or other equipment types.

Turning next to FIG. 2B a view of an embodiment of showerhead 108 is shown along cross-section “a-a” of FIG. 1. Showerhead 258 is another embodiment of showerhead 108. FIG. 2B illustrates an example showerhead 258 comprising a star pattern, for example, of gas delivery tubes 252. Showerhead 258 comprises gas delivery tubes 252, and in this embodiment, twenty-five gas delivery tubes 252 are illustrated. Gas delivery tubes 252 are an embodiment of multi-channel gas delivery tubes 122 in FIG. 1. Each gas delivery tube 252 comprises outer sub-tube 256 and inner sub-tube 254. As in FIG. 2A, the gases that flow in outer sub-tube 256 and the gases that flow in inner sub-tube 254 are independent of each other and do not mix until expelled into the chamber. Any practical number and size of gas delivery tubes 252 may be employed in showerhead 258. Other patterns of multi-channel gas delivery tubes may be employed. Further, other shaped multi-channel gas delivery tubes may be employed, such as open-ended cones, open-ended cube shapes, or the like.

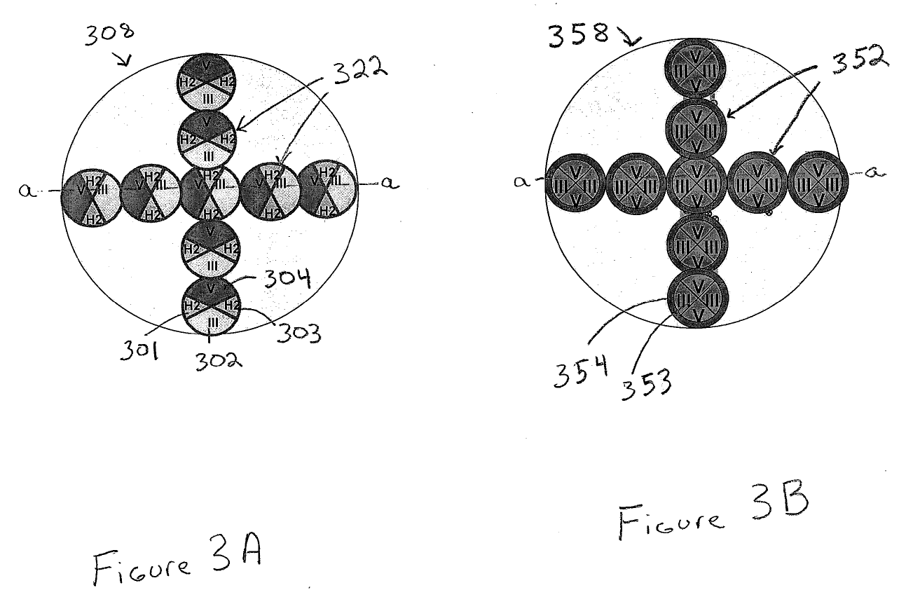

FIGS. 3A and 3B illustrate further embodiments of showerheads with multi-channel gas delivery tubes. Turning first to FIG. 3A, a view of an embodiment of showerhead 108 is shown along cross-section “a-a” of FIG. 1. In this embodiment, the multi-channel gas delivery tubes of FIG. 1 comprise four-channel gas delivery tubes 322 configured in a cross pattern. Four-channel gas delivery tubes 322 show an example of multi-channel gas delivery tubes 122 partitioned into four portions. In this embodiment the channels do not hold an equal volume of gas, however it is within the scope of these embodiments that the channels hold any practical volume of gas in proportion to each other, including volumes of equal proportions. Each channel of this embodiment emits a gas unmixed with the other channels into the chamber. Further, in the specific example discussed above, Group V, Group III, and example carrier gas H₂ flow simultaneously within four-channel gas delivery tubes 322. Thus, more than one channel may flow the same gas in an embodiment, or each channel may flow a different gas.

Turning next to FIG. 3B, a view of an embodiment of showerhead 108 is shown along cross-section “a-a” of FIG. 1. Showerhead 358 comprises five-channel gas delivery tubes 352. Each five-channel gas delivery tube 352 is partitioned into an inner sub-tube 353 and an outer sub-tube 354. Inner sub-tube 353 is further partitioned into four channels such as four-channel gas delivery tubes 322 in FIG. 3A. Thus, five channels are employed. Each of the five channels is independent of the others and may flow a different gas unmixed into the chamber (not shown). Therefore, a first gas may encircle four different gases flowing through five-channel gas delivery tubes 352. The first gas may be a carrier gas that encircles the four different gases of the inner sub-tube 353 as the gases are emitted from five-channel gas delivery tube 352.

In the specific embodiment illustrated, carrier gas H₂ flows in outer sub-tube 354 and inner sub-tube 353 flows a Group V gas and a Group III gas. Thus, in this embodiment, 1, 2, 3, 4 or 5 gases may be emitted simultaneously into the chamber. The flow rate of each of the five gases may be controlled independently, or like gases may be controlled together.

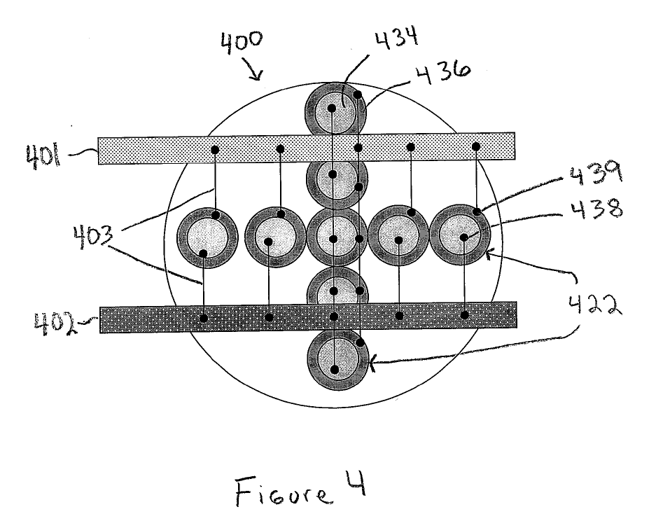

FIG. 4 illustrates gas interconnections and inlets, which may be included in the showerhead, in accordance with an embodiment of the present invention. Showerhead 400 comprises two-channel gas delivery tubes 422, such as multi-channel gas delivery tubes 122 in FIG. 1, for purposes of illustration only. Gas interconnect pipes 401 and 402 are interconnected to minor gas pipes 403, which are in turn connected to multi-channel gas delivery tubes 422, through gas inlets, such as 438 and 439.

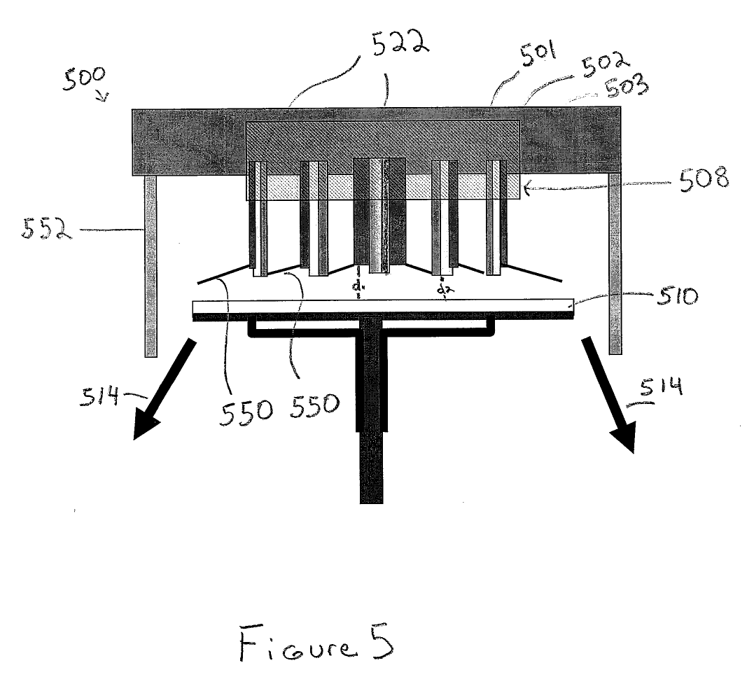

FIG. 5 illustrates an embodiment of a plural gas distribution system including chamber baffles 550. Plural gas distribution system 500 is similar to plural gas distribution system 100 in FIG. 1. Plural gas distribution system 500 includes showerhead 508. Showerhead 508 is an embodiment of showerhead 108 in FIG. 1. Showerhead 508 comprises multi-channel gas delivery tubes 522, which are an embodiment of multi-channel gas delivery tubes 122 of FIG. 1. Multi-channel gas delivery tubes 522 include channels for three different gases, such as gas 1, gas 2, and gas 3 in sub-tube 501, sub-tube 502, and sub-tube 503, respectively. Note that sub-tubes 501, 502, and 503 may be of different lengths, and therefore different distances to workpiece 510, such as distances d1 and d2. The distance from multi-channel gas delivery tubes 522 may be adjustable and/or programmable through a controller, such as controller 106 in FIG. 1. From one multi-channel gas delivery tube to another, the distance to workpiece 510 may vary across showerhead 508.

Plural gas distribution system 500 also shows baffles 550. Baffles 550 direct gas flows towards workpiece 510 and exhaust ports 514. Moreover, baffles 550 block gas from flowing into upper chamber 552 and re-entering showerhead 508. Thus, combinations of gases and gas by-products are prevented from contaminating showerhead 508 and upper chamber 552. Baffles 550 may be positioned adjacent to each multi-channel gas delivery tube 522.

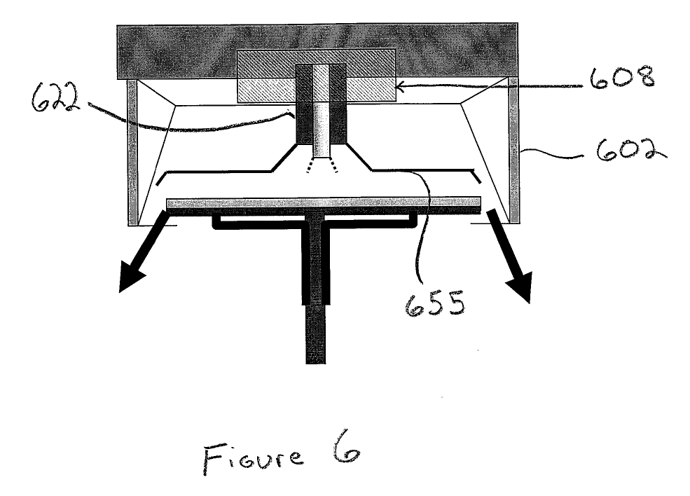

FIG. 6 illustrates an embodiment of a plural gas distribution system wherein the showerhead comprises one gas delivery tube. Chamber 602 comprises showerhead 608, which includes an embodiment of a single multi-channel gas delivery tube. Each channel may be used for a different gas or multiple channels may be used for the same gas. In the example shown, the gas delivery tube comprises a five-channel gas delivery tube 622, which emits three independent gases through sub-tubes. Baffle 655 directs the gases towards the exhaust and discourages gases from filling the upper portion of chamber 602 or back flowing into showerhead 608.

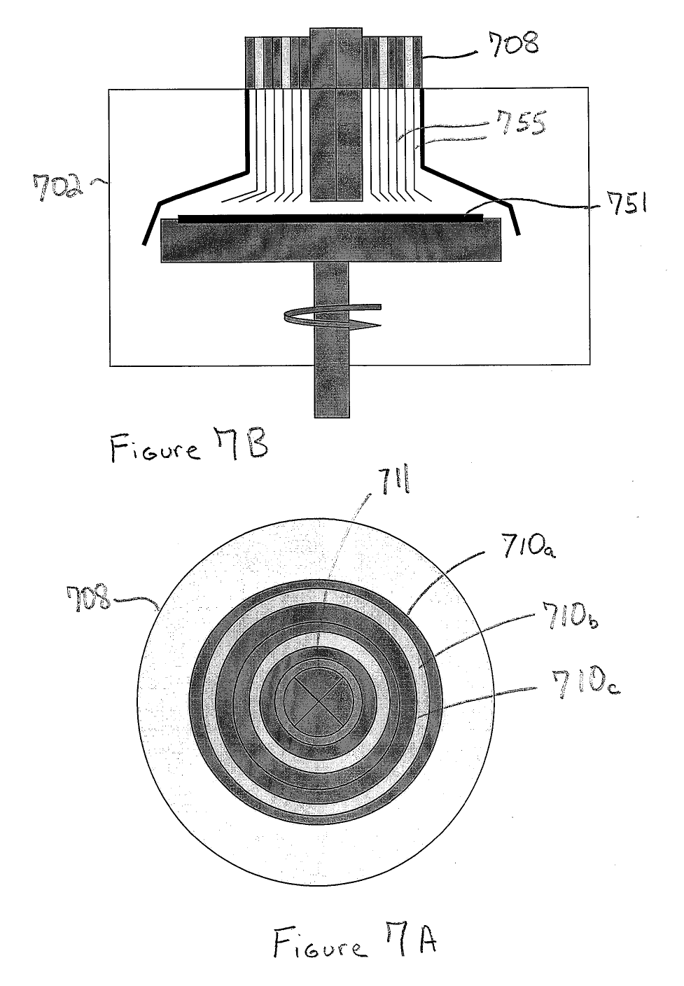

FIGS. 7A and 7B illustrate and embodiment of a plural gas distribution system with a concentric circle showerhead708 and concentric circle baffles 755. Turning first to FIG. 7A and the detail of showerhead 708, multi-channel gas delivery tube 722 includes independent concentric sub-tubes 710. Independent concentric sub-tubes 710 may be thought of as multiple outer sub-tubes. The inner sub-tube 711 comprises a sub-tube with four-channels. Independent concentric sub-tubes 710a, 710b, and 710c may deliver the different gases to chamber 702. Independent concentric sub-tubes 710 may have small holes on the workpiece side of the circular tubes that allow the gas to flow into baffles 755 (see further discussion of baffles below).

Looking at FIG. 7B chamber 702 is configured to accept showerhead 708. Showerhead 708 is configured to dispense gas into the concentric baffles 755 that extend from showerhead 708 down towards workpiece 751. Baffles 755 may flair at the workpiece side of baffles 755, further directing the flow of gases uniformly around workpiece 751.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A plural gas distribution system, the system comprising:
a chamber, wherein the chamber is configured to contain and to exhaust a plurality of gases;
a showerhead within the chamber, the showerhead comprising at least one multi-channel gas delivery tube; and
at least two sub-tubes within the at least one multi-channel gas delivery tube, wherein the at least two sub-tubes are configured to simultaneously expel gases unmixed into the chamber.

2. The system of claim 1, further comprising at least one baffle adjacent to the at least one multi-channel gas delivery tube.

3. The system of claim 1, wherein the at least two sub-tubes comprise an inner sub-tube encircled by an outer sub-tube, wherein the inner sub-tube is isolated from the outer sub-tube.

4. The system of claim 3, wherein the inner sub-tube is further comprised of a structure configured to divide an inside of the inner sub-tube into multiple volumes, wherein each volume of the multiple volumes is isolated from each other volume of the multiple volumes.

5. The system of claim 4, wherein the inner sub-tube is encircled by n outer sub-tubes, wherein n is an integer.

6. The system of claim 3, wherein the inner sub-tube is encircled by n outer sub-tubes, wherein n is an integer.

7. The system of claim 3, wherein a sub-tube of the at least two sub-tubes has an adjacent baffle.

8. The system of claim 1 further comprising a controller, wherein the controller controls one or more of a platen temperature, a platen rotation, a chamber pressure, and an input gas area.

9. The system of claim 8 further comprising a platen, wherein a distance between the platen and the at least one multi-channel gas delivery tube is variable, wherein the distance is controlled by the controller.

10. The system of claim 9, wherein a diameter of the at least one multi-channel gas delivery tube is less than about one-fifth a diameter of the platen.

11. The system of claim 9, wherein the at least one multi-channel gas delivery tube comprises an outlet hole having a diameter less than about one-tenth a diameter of the platen.

12. The system of claim 9, wherein the platen is configured to hold a plurality of workpieces.

13. The system of claim 9, wherein a distance d1 is the distance between a first sub-tube and a platen, and a distance d2 is the distance between a second sub-tube and the platen, wherein the distance d1 is not equal to the distance d2.

14. A plural gas distribution showerhead apparatus, the apparatus comprising:
a gas input area configured to simultaneously input a plurality of gases; and
a multi-channel gas delivery tube comprising a plurality of sub-tubes, the plurality of sub-tubes configured such that the plurality of gases remain unmixed through the plurality of sub-tubes of the multi-channel gas delivery tube.

15. The apparatus of claim 14, wherein the multi-channel gas delivery tube comprises an inner sub-tube encircled by an outer sub-tube, wherein each gas of the plurality of gases is confined to flow in only one of the inner sub-tube or the outer sub-tube.

16. The apparatus of claim 15, wherein the inner sub-tube further comprises a structure configured to divide an inside of the inner sub-tube into multiple volumes, wherein each gas of the plurality of gases is free to flow independently through a volume of the multiple volumes of the inner sub-tube.

17. The apparatus of claim 14 further comprising a structure configured to divide an inside of the multi-channel gas delivery tube into multiple volumes, wherein each gas of the plurality of gases is free to flow independently through a volume of the multiple volumes of the multi-channel gas delivery tube.

18. The apparatus of claim 14, wherein the showerhead apparatus comprises a first sub-tube encircled by a second sub-tube, the second sub-tube encircled by an n sub-tube, wherein each gas of the plurality of gases is confined to flow in only one of the first sub-tube, the second sub-tube, and the n sub-tube, wherein n is an integer.

19. A semiconductor manufacturing plural gas distribution system, the system comprising:
a controller;
a gas input area, wherein the controller is configured to independently control a gas flow of each of a plurality of gases out of the gas input area;
a chamber configured to exhaust the plurality of gases;
a showerhead within the chamber, wherein the showerhead receives the plurality of gases, and wherein the showerhead comprises at least one multi-channel gas delivery tube, wherein a first gas and a second gas of the plurality of gases are delivered simultaneously and unmixed to at least one workpiece in the chamber; and
a platen configured to hold the at least one workpiece.

20. The system of claim 19 further comprising at least one baffle in the chamber.
